(19) United States
(12) Patent Application Publication
(10) Pub. No.: US 2010/0085129 A1
(43) Pub. Date: Apr. 8, 2010

(54) IMPEDANCE MATCHING APPARATUS FOR PLASMA-ENHANCED REACTION REACTOR

(75) Inventors: Mitsutoshi Shuto, Tokyo (JP); Yasuaki Suzuki, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/246,410

(22) Filed: Oct. 6, 2008

(51) Int. Cl. H03H 7/38

(52) U.S. Cl. 333/32

(57) ABSTRACT

An impedance matching apparatus adapted to be connected between a reaction chamber and a power source for plasma processing includes a transformer, a coil unit, and a capacitor connected in series. A primary side of the transformer is adapted to be connected to the power source, and a secondary side of the transformer has multiple taps positioned at different windings; and the coil unit is comprised of multiple coils having different inductances and arranged in parallel, wherein each tap is connected to a different coil or coils. The impedance matching circuit further includes a switch unit provided between the coil unit and the capacitor.

### BACKGROUND

1. Field of the Invention

The present invention relates to an impedance matching apparatus for high-frequency plasma processing, as well as a plasma processing apparatus using said impedance matching apparatus.

2. Description of the Related Art

As shown in FIG. 1, an apparatus that utilizes high-frequency power like a plasma CVD apparatus has a matching apparatus 2 installed between its high-frequency power supply 3 and reaction chamber 1 for efficient use of high-frequency power.

If the frequency of high-frequency power is low, or, say, 10 MHz or less, the change in reactor impedance during plasma process is often small. When the impedance does not change much during plasma processing, as in the aforementioned case, the matching circuit can be formed by a coil L1, capacitor C1 and transformer Tr. This circuit cancels out and thereby reduces the imaginary-number component of the reactor impedance through the series circuit constituted by the coil L1 and capacitor C1, and also converts the impedance through the transformer Tr. The aforementioned fixed coil L1 and transformer Tr are formed using one toroidal core or multiple toroidal cores stacked on top of one another.

In a circuit like this, achievement of impedance matching according to the change in reactor impedance requires that either the value of the coil or capacitor be changed along with the two circuit constant values pertaining to the transformer winding ratio.

In conventional apparatuses, multiple taps are provided on the secondary side of the transformer and if impedance matching is lost due to a change in reactor impedance as a result of changing the film forming condition or apparatus configuration, then the transformer taps T1, T2, T3, T4 must be changed manually and the coil L1 or capacitor C1 must be replaced, as well.

Alternatively, taps are provided for the coils, in addition to those on the secondary side of the transformer, and both taps are changed manually according to the change in reactor impedance.

### SUMMARY

However, switching taps and replacing the coil or capacitor every time a process involving a different impedance is implemented requires a lot of time and also presents other problems such as the replacement of parts making the process prone to human errors. In addition, the method of providing and switching transformer and coil taps make the circuit complex because there are two switching points, and also presents other problems such as making the process prone to switching errors and other operational errors.

In an embodiment of the present invention capable of solving at least one of the aforementioned problems, a matching circuit consisting of a transformer, coils and capacitor has several different taps at the transformer, where each tap is connected to a coil, as well as a switch between the coils and capacitor. In an embodiment, several combinations of transformer taps and coils are created beforehand to match the desired reactor impedances to be accommodated. In an embodiment, all of the aforementioned coils are created around the same toroidal core.

According to the aforementioned embodiments, multiple impedances can be accommodated with a single switching point. In particular, the embodiment where multiple coils are wound around the same toroidal core provides a matching apparatus that is smaller and more inexpensive than conventional matching apparatuses where coils are created around different toroidal cores.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a conventional impedance matching circuit of an impedance matching apparatus provided between a reaction chamber and a radio-frequency power source.

FIG. 2 is an impedance matching circuit according to an embodiment.

FIG. 3 is an impedance matching circuit according to another embodiment.

FIG. 4 is an impedance matching circuit according to still another embodiment.

FIG. 5 is an impedance matching circuit according to yet another embodiment.

### DETAILED DESCRIPTION

The present invention will be explained with reference to embodiments which are not intended to limit the present invention.

An embodiment of the present invention provides an impedance matching apparatus having an impedance matching circuit and being adapted to be connected between a reaction chamber and a power source for plasma processing, said impedance matching circuit comprising a transformer, a coil unit, and a capacitor connected in series, wherein (i) a primary side of the transformer is adapted to be connected to the power source, and a secondary side of the transformer has multiple taps positioned at different windings; and (ii) the coil unit is comprised of multiple coils having different inductances and arranged in parallel, wherein each tap is connected to a different coil or coils; (iii) said impedance matching circuit further comprising a switch unit provided between the coil unit and the capacitor, wherein the switch unit has multiple input terminals connected to different coils of the coil unit, and an output terminal connected to the capacitor, wherein by switching the one of the multiple input terminals that is connected to the output terminal, different combinations of the coils and the taps are selectable to match the impedance of the reaction chamber.

In an embodiment, the multiple input terminals may be switchable based on a signal indicative of an impedance change from the reaction chamber. This can be accomplished automatically or manually. The skilled artisan will appreciate that the apparatus includes one or more controller(s) programmed or otherwise configured to cause the switching described elsewhere herein to be automatically conducted. The controller(s) can communicate with the power source, the reaction chamber, and the impedance matching apparatus, as will be appreciated by the skilled artisan.

In any of the foregoing embodiments, the coils may be wound into a same toroidal core.

Another embodiment of the present invention provides an impedance matching apparatus having an impedance matching circuit and being adapted to be connected between a reaction chamber and a power source for plasma processing, said impedance matching circuit comprising a transformer, a coil unit, a switch unit, a coil, and a capacitor connected in series, wherein (I) a primary side of the transformer is adapted to be connected to the power source, and a secondary side of the transformer has multiple taps positioned at different winds; (II) the coil unit is comprised of multiple coils arranged in parallel connected to two or more of the taps; and (III) the switch unit has multiple input terminals connected to different coils of the coil unit, and an output terminal connected to the capacitor, wherein by switching the multiple input terminals to be connected to the output terminal, different combinations of the coils and the taps are selectable to match the impedance of the reaction chamber, wherein all of the coils in the impedance matching circuit are wound into a same toroidal core.

Another aspect of the present invention provides a plasma reactor comprising a reaction chamber, a power source, and any of the foregoing impedance matching apparatus connected between the reaction chamber and the power source.

In an embodiment, the power source may supply radio-frequency power having a frequency of 10 MHz or lower.

Still another aspect of the present invention provides a method for matching impedance of a reaction chamber to which radio-frequency power is supplied via an impedance matching apparatus having an impedance matching circuit comprised of a transformer, a coil unit, a switch unit, and a capacitor, comprising: (a) providing multiple taps in a secondary side of the transformer at different positions; (b) providing multiple coils having different inductances for the coil unit, the multiple coils wound into a same toroidal core; (c) providing combinations of the taps and the coils connected to each other; (d) providing the coils connected to input terminals of the switch unit and providing an output terminal of the switch unit connected to the capacitor; (e) choosing one of the combinations of the taps and the coils and supplying radio-frequency power to the reaction chamber via the impedance matching apparatus; and (f) switching between the combinations of the taps and the coils by the switch unit according to changes of impedance of the reaction chamber.

In an embodiment, the power source may supply radio-frequency power having a frequency of 10 MHz or lower.

In any of the foregoing embodiments, the impedance matching apparatus may further comprise another coil connected in series between the capacitor and the reaction chamber, said another coil being wound into the same toroidal core.

In any of the foregoing embodiments, the supplied power may generate a plasma in the reaction chamber for plasma-enhanced CVD. In another embodiment, the supplied power may generate a plasma in the reaction chamber for plasma-enhanced ALD, plasma etching, etc.

In at least one embodiment, by a single switching operation, the impedance matching apparatus can compensate for changes of the impedance of the reaction chamber. Further, in at least one embodiment, by winding all of the coils into the same toroidal core, the number of windings can significantly be reduced, and as a result, the impedance matching apparatus can be downsized and inexpensive.

Specific examples will be explained in detail with reference to drawings which are not intended to limit the present invention. The numerical numbers applied in specific examples may be modified in an embodiment by a range of at least ±50%, wherein the endpoints of the ranges may be included or excluded. In the present disclosure where conditions and/or structures are not specified, the skilled artisan in the art can readily provide such conditions and/or structures, in view of the present disclosure, as a matter of routine experimentation.

A matching apparatus conforming to an embodiment of the invention described in the present application for patent can be applied according to the basic configuration shown in FIG. 1. To be specific, this matching apparatus can be installed between the high-frequency power supply 3 and reaction chamber 1 to operate as high-frequency power is supplied from the high-frequency power supply 3 to the electrodes in the reaction chamber 1. Take note that this matching apparatus can be applied not only for plasma CVD apparatuses, but also for all other apparatuses using plasma such as plasma etching apparatuses and plasma ALD apparatuses.

The matching circuit inside the matching apparatus typically has (but not limited to) a structure that consists of a transformer Tr having multiple taps, multiple coils all wound around one toroidal core and respectively connected to each tap, fixed capacitor C1, and switch S.

In an embodiment, the transformer Tr is created using a toroidal core, and two or more taps are provided on the secondary side of the transformer. Each tap is connected to a coil having a different winding number, and the other end of the coil is connected to each terminal of the switch S. All of these multiple coils are created by being wound around the same toroidal core.

In an embodiment, a capacitor is installed as the destination of the switch, and this capacitor is connected to the electrodes in the reaction chamber. The switch can be switched manually or using signals from the apparatus, and this switch alone is used to change the transformer-coil combination.

In an embodiment, the transformer taps, coils and capacitor form a series circuit, where the position of each tap and winding number of each coil are determined in such a way as to match each target impedance.

Materials that can be used to form the toroidal core are largely divided into ferrite materials and carbonyl iron materials. Ferrite materials are further divided into nickel zinc ferrite materials and manganese zinc ferrite materials. Of these materials, carbonyl iron materials generate minimal losses at high frequency and therefore the toroidal core used in the matching apparatus is desirably made of a carbonyl iron material. It should be noted, however, that toroidal core materials are not at all limited to those mentioned above. It is also possible to change the toroidal core size or provide double or triple toroidal cores according to the electric power used or desired impedance to be achieved.

Toroidal cores are ideal because of their favorable characteristics that include causing little magnetic flux leak or contact with adjacent components and offering favorable repeatability. In addition to toroidal cores, however, air cores and bar cores can also be used.

For your information, the positions of respective taps and winding numbers of respective coils are determined in a manner achieving matching effects with target impedances, where the number of target impedances varies depending on various conditions such as the type of plasma processing to be implemented. However, the number of target impedances is not a limiting factor, and a desired number of combinations can be created to accommodate as many target impedances as required.

It should also be noted that those skilled in the art should be able to select an appropriate winding number on the primary side of the transformer, winding number at the position of each tap on the secondary side of the transformer, winding number of each coil, capacity of the capacitor, etc., according to the load impedance. In an embodiment, the capacitor is made constant and thus use of a different load necessitates changing the coil and transformer winding numbers. In this case, however, these different winding numbers are fixed for a given load.

### EXAMPLE 1

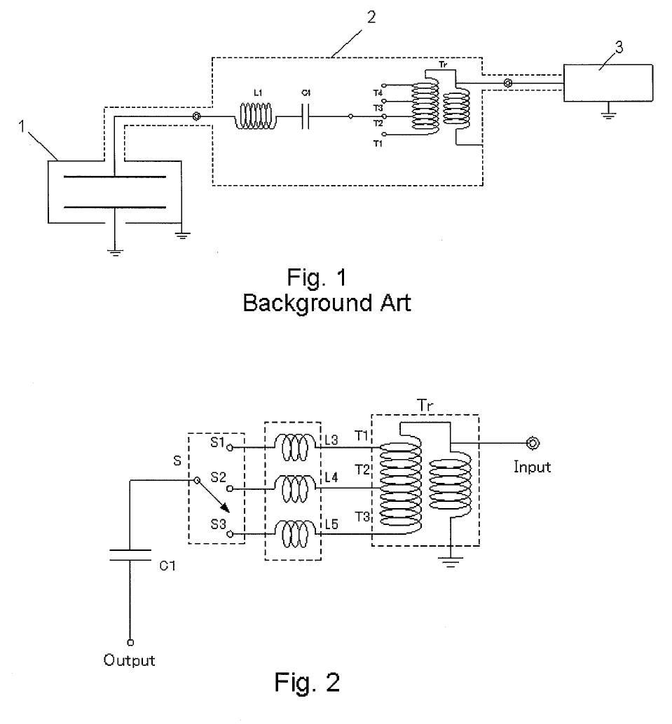

An example of the invention described in the present application for patent is explained below using FIG. 2 and actual values.

The matching apparatus used in this example is installed between the high-frequency power supply and reaction chamber to operate as high-frequency power is supplied from the high-frequency power supply to the electrodes in the reaction chamber.

The matching circuit inside the matching apparatus consists of a transformer Tr having multiple taps, multiple coils all wound around one toroidal core and respectively connected to each tap, fixed capacitor C1, and switch S.

The transformer Tr is created using a toroidal core. The primary side of the transformer has 28 windings, and three taps are provided on the secondary side. Each tap is connected to a coil having a different winding number, and the other end of the coil is connected to each terminal of the switch S. All these three coils are created by being wound around the same toroidal core.

The switch S can be switched using signals from the apparatus. A desired tap-coil combination can be selected by switching this switch S.

A capacitor C1 is installed as the destination of the switch, and this capacitor C1 is connected to the electrodes in the reaction chamber.

The position at which each of the aforementioned taps is provided, and the winding number of each of the aforementioned coil, are determined according to each target impedance. Here, three film forming conditions A, B and C, each involving a different reactor impedance, are used as examples to explain the aforementioned matching apparatus.

Table 1 summarizes the reactor impedance under each film forming condition and the transformer winding numbers and coil winding number needed to match the impedance.

TABLE 1
Transformer and coil winding numbers required under each condition

| | | | Transformer | | | |
|---|---|---|---|---|---|---|
| | | | Winding | | | |
| | | | number | Winding | | |
| | | | on | number on | Winding | Coil |
| | Reactor | | primary | secondary | number | winding |
| | impedance | Capacitor C1 | side | side | ratio N | number |
| Condition A | 120-55j Ω | 12000 pF | 28 | 44 | 1.57 | 16 |
| Condition B | 220-190j Ω | | | 58 | 2.07 | 27 |
| Condition C | 235-135j Ω | | | 63 | 2.25 | 21 |

When the invention described in the present application for patent is applied to the above three different film forming conditions, all you need is to provide taps according to the respective conditions, create coils having different winding numbers around one toroidal core, and then connect the taps and coils, as shown in Table 2.

TABLE 2
Required tap-coil combinations

| | |
|---|---|
| Transformer | Coil |

| | Winding number on | | Winding | |
|---|---|---|---|---|
| Tap | secondary side | | number | Target |
| Tap1 | 44 | L1 | 16 | Condition A |
| Tap2 | 58 | L2 | 27 | Condition B |
| Tap3 | 63 | L3 | 21 | Condition C |

This way, matching can be achieved simply by switching the switch to S1 when film forming condition A is implemented, to S2 when film forming condition B is implemented, or to S3 when film forming condition C is implemented.

As explained above, multiple conditions can be accommodated with a very simple circuit of the same size as traditional circuits, by creating a tap-coil combination for each target and then creating all coils in the created tap-coil combinations around the same toroidal coil.

Although three combinations of transformer taps and coils were used in this example, the number of combinations need not be three and normally a desired number of combinations are created for as many target impedances as required. At this time, the winding number at the position of each transformer tap, and winding number of each coil, are all determined according to each of these target impedances.

It should also be noted that while the switch S was switched using signals from the apparatus in this example, it is also possible to use a tap or rotary switch to implement manual switching.

### EXAMPLE 2

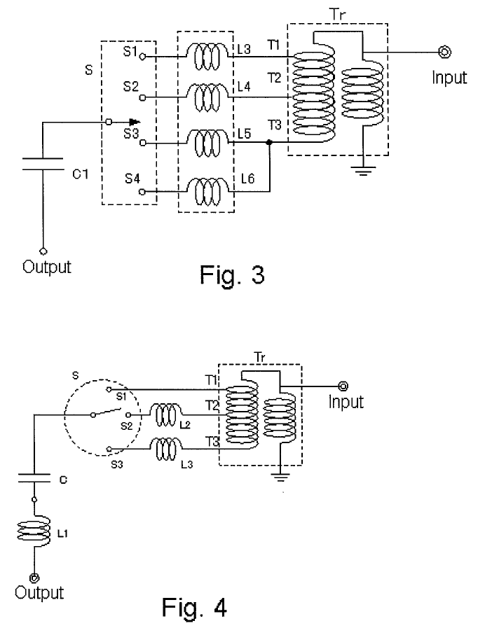

A different example is explained. In Example 1, one coil was connected to each tap. However, multiple coils can be connected to each tap, as shown in FIG. 3. In this case, however, all coils are still created around the same toroidal core. This method can also accommodate multiple impedances using a single switching point.

Note that in FIG. 3, two coils are connected to the T3 tap of the transformer. However, multiple coils can be connected to other tap or taps.

### EXAMPLE 3

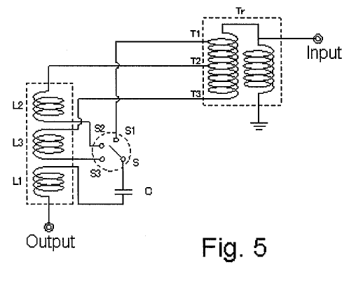

As shown in FIG. 4, a different matching circuit is also conceivable where not the coils alone, but both the coils and capacitor, are installed between the switch and reaction chamber and the two coils are connected in series. Even when all coils are connected in series, as in the aforementioned case, two or more coils can be created around the same toroidal core, as shown in FIG. 5.

TABLE 4
Comparison of creating coils around different toroidal cores and same toroidal core at S

| | L1 | | L2 | | |
|---|---|---|---|---|---|
| | Winding | Inductance | Winding | Inductance | Total inductance |
| | number | (μH) | number | (μH) | of L1 and L2 (μH) |
| One coil | 27 | 68.4 | — | — | 68.4 |
| Coils created around | 24 | 54.0 | 13 | 15.0 | 69.0 |
| different toroidal cores | | | | | |
| Coils created around | 14 | 32.9 | 13 | 35.5 | 68.4 |
| same toroidal core | | | | | |

As shown above, creating coils L1 and L2, or L1 and L3, or any other combination of coils connected in series, around the same toroidal core achieves greater inductance values compared to when the same coils are created around different toroidal cores, when the winding numbers are the same. For example, a single coil having 27 windings provides an inductance of 68.4 μH, as shown in Table 4. When two coils are created around different toroidal cores and L2 is wound 13 times, on the other hand, L1 needs to be wound 24 times in order to achieve the same inductance. In the meantime, creating two coils around the same toroidal core and winding L2 13 times requires L1 to be wound only 14 times. Here, the achieved inductance is evidently different from when L1 and L2 are used independently, and the coil winding numbers are also reduced, which in turn reduces coil losses.

These effects can be achieved because the coils L1 and L2 wound around the same toroidal core are connected in series and the same amount of current flows through both coils, and consequently the two coils have the characteristics of a single coil.

### EFFECTS

At least one embodiment of the invention described in the present application for patent allows multiple impedances to be accommodated with a single switching point, and furthermore provides a small, more inexpensive matching apparatus where multiple coils are wound around the same toroidal core.

The present invention includes the above mentioned embodiments and other various embodiments including the following:

1) A matching apparatus installed between the power supply and reaction chamber of a plasma processing apparatus and having a matching circuit consisting of a series circuit, coils and a capacitor; wherein said matching apparatus has multiple taps on the secondary side of the aforementioned transformer, with each tap connected to one or multiple coils, while a switch is provided between the aforementioned multiple coils and capacitor to allow the tap-coil combination to be changed by switching this switch in order to accommodate multiple impedances.

2) A matching apparatus according to 1) above, wherein said matching apparatus is characterized in that the switch in the matching circuit can be switched using signals from the apparatus.

3) A matching apparatus according to 1) above, wherein said matching apparatus is characterized in that all of the multiple coils in the matching circuit are created around the same toroidal core.

4) A matching apparatus having a matching circuit that consists of a transformer having multiple taps on the secondary side, multiple coils connected to each taps, switch for changing the coil-transformer combination, and coil and capacitor provided between the switch and the output of the matching apparatus; wherein said matching apparatus is characterized in that all of the multiple coils in the matching circuit are created around the same toroidal core.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. An impedance matching apparatus having an impedance matching circuit and being adapted to be connected between a reaction chamber and a power source for plasma processing, said impedance matching circuit comprising a transformer, a coil unit, and a capacitor connected in series, wherein
a primary side of the transformer is adapted to be connected to the power source, and a secondary side of the transformer has multiple taps positioned at different windings; and
the coil unit is comprised of multiple coils having different inductances and arranged in parallel, wherein each tap is connected to a different coil or coils;
said impedance matching circuit further comprising a switch unit provided between the coil unit and the capacitor, wherein the switch unit has multiple input terminals connected to different coils of the coil unit, and an output terminal connected to the capacitor, wherein the switch unit allows one of the multiple input terminals to be connected to the output terminal, wherein by switching the one of the multiple input terminals connected to the output terminal, different combinations of the coils and the taps are selectable to match the impedance of the reaction chamber.

2. The impedance matching apparatus according to claim 1, wherein the multiple input terminals are switchable based on a signal indicative of an impedance change from the reaction chamber.

3. The impedance matching apparatus according to claim 1, wherein the coils are wound into a same toroidal core.

4. An impedance matching apparatus having an impedance matching circuit and being adapted to be connected between a reaction chamber and a power source for plasma processing, said impedance matching circuit comprising a transformer, a coil unit, a switch unit, a coil, and a capacitor connected in series, wherein
a primary side of the transformer is adapted to be connected to the power source, and a secondary side of the transformer has multiple taps positioned at different windings;
the coil unit is comprised of multiple coils arranged in parallel, the coils connected to two or more of the taps; and
the switch unit has multiple input terminals connected to different coils of the coil unit, and an output terminal connected to the capacitor, wherein the switch unit allows one of the multiple input terminals to be connected to the output terminal, wherein by switching the one of the multiple input terminals connected to the output terminal, different combinations of the coils and the taps are selectable to match the impedance of the reaction chamber.

5. A plasma reactor comprising a reaction chamber, a power source, and the impedance matching apparatus of claim 1 connected between the reaction chamber and the power source.

6. The plasma reactor according to claim 5, wherein the power source supplies radio-frequency power having a frequency of 10 MHz or lower.

7. A plasma reactor comprising a reaction chamber, a power source, and the impedance matching apparatus of claim 4.

8. The plasma reactor according to claim 7, wherein the power source supplies radio-frequency power having a frequency of 10 MHz or lower.

9. The plasma reactor according to claim 4, wherein all of the coils in the impedance matching circuit are wound into a same toroidal core.

10. A method for matching impedance of a reaction chamber to which radio-frequency power is supplied via an impedance matching apparatus having an impedance matching circuit comprised of a transformer, a coil unit, a switch unit, and a capacitor, comprising:
providing multiple taps in a secondary side of the transformer at different positions;
providing multiple coils having different inductances for the coil unit;
providing combinations of the taps and the coils connected to each other;
providing the coils connected to input terminals of the switch unit and providing an output terminal of the switch unit connected to the capacitor;
choosing one of the combinations of the taps and the coils and supplying radio-frequency power to the reaction chamber via the impedance matching apparatus; and
switching the combinations of the taps and the coils by the switch unit according to changes of impedance of the reaction chamber.

11. The method according to claim 10, wherein the power source supplies radio-frequency power having a frequency of 10 MHz or lower.

12. The method according to claim 10, wherein the impedance matching apparatus further comprises another coil connected in series between the capacitor and the reaction chamber, said another coil being wound into the same toroidal core.

13. The method according to claim 10, wherein the supplied power generates a plasma in the reaction chamber for plasma-enhanced CVD.

14. The method according to claim 10, wherein the multiple coils are wound into a same toroidal core
